(19) United States
(12) Patent Application Publication
(10) Pub. No.: US 2010/0301010 A1
(43) Pub. Date: Dec. 2, 2010

(54) ETCHANT COMPOSITIONS AND ETCHING METHOD FOR METALS Cu/Mo

(75) Inventors: Cheng Wei Lin, Taiwan (CN); Mo Hsun Tsai, Taiwan (CN)

Correspondence Address: OBLON, SPIVAK, MCCLELLAND MAIER & NEUSTADT, L.L.P., 1940 DUKE STREET, ALEXANDRIA, VA, 22314, US

(73) Assignee: BASF SE, LUDWIGSHAFEN (DE)

(21) Appl. No.: 12/675,131

(22) PCT Filed: Oct. 2, 2008
(86) PCT No.: PCT/EP2008/063221

§ 371 Date: Feb. 25, 2010

(30) Foreign Application Priority Data
Oct. 8, 2007 (TW) 096137710
Oct. 22, 2007 (CN) 200710167317.4

(51) Int. Cl. C23F 1/02; C09K 13/00; C09K 13/08; C09K 13/06; C25D 5/48; C23C 14/34

(52) U.S. Cl. 216/41; 252/79.1; 252/79.3; 252/79.4; 205/221; 204/192.15

(57) ABSTRACT

The present invention provides an etchant composition suitable for etching metals Cu/Mo, wherein the composition comprises 1 to 25 wt % of hydrogen peroxide on the basis of the total weight of the composition; 0.1 to 15 wt % of amino acid on the basis of the total weight of the composition; 0.1 to 15 wt % of a pH stabilizer on the basis of the total weight of the composition; 0.01 to 2 wt % of fluorine-containing acid on the basis of the total weight of the composition; 0.01 to 3 wt % of an acidic pH adjuster on the basis of the total weight of the composition; and an aqueous medium. The present invention also provides a process for etching metals Cu/Mo with the etchant composition of the present invention.

### BACKGROUND OF THE INVENTION

1. Field of the Invention

The present invention relates to an etchant composition suitable for etching and defining an etching pattern for Cu/Mo bi-layers. The etchant composition of the invention is applicable to the etching processes of flat-panel displays, integrated circuits, flip chips, printed circuit boards, color filters, micro-electro machines, or other applications of Cu/Mo bi-layers.

2. Description of the Prior Art

As semiconductors, flat-panel displays and micro-electro machines are developing larger sizes and high response rates, the conventional aluminum wire cannot meet the requirements for electron migration rates. Therefore, metal materials with lower resistance (e.g., copper), which have the advantage of improving current transmitting rate, are adopted as wires. However, although copper has the advantage of low resistance, copper still has two disadvantages: it is prone to oxidization and incapable of being dry etched. Furthermore, the adhesion between copper and glass substrates or silicon substrates is also poor. It is difficult to apply copper wires in practice. Nevertheless, adding a molybdenum layer between copper and the substrate can solve the problem of adhering copper wires to the substrate. Thus, Cu/Mo bi-layers become a main structure during the development of metal wires.

However, in the etching processes based on Cu/Mo bi-layers, the following problems occur and need to be solved:
1. It is difficult to eliminate the difference in the selection ratio of the Cu/Mo etching rate.
2. The CD loss of the wire is too large.
3. The oblique angle of the wire sides is larger than or equal to 90°.

After extensive research, the inventors of the present invention found that using the etchant composition of the present invention to etch Cu/Mo bi-layers could effectively solve the above problems.

### SUMMARY OF THE INVENTION

Accordingly, the present invention provides an etchant composition suitable for etching metals Cu/Mo, wherein the composition comprises 1 to 25 wt % of hydrogen peroxide on the basis of the total weight of the composition; 0.1 to 15 wt % of amino acid on the basis of the total weight of the composition; 0.1 to 15 wt % of a pH stabilizer on the basis of the total weight of the composition; 0.01 to 2 wt % of fluorine-containing acid on the basis of the total weight of the composition; 0.01 to 3 wt % of an acidic pH adjuster on the basis of the total weight of the composition; and an aqueous medium.

The etchant composition of the invention has the advantages of achieving stable and uniform etching rates, and low under cut and appropriate under cut rim angle, when being used to form Cu/Mo electric circuit patterns.

The present invention also provides a process for etching metals Cu/Mo with the etchant composition of the present invention.

### BRIEF DESCRIPTION OF THE DRAWINGS

FIG. 1 is a side view of a laminate after it is etched with the etchant composition of the invention.

FIG. 2 is an optical microscope photograph, enlarged 1000 times, of a laminate after it is etched with the etchant composition of the invention.

FIG. 3 is a top view of a laminate after it is etched with the etchant composition of the invention and the photoresist is removed.

### DETAILED DESCRIPTION OF THE INVENTION

The etchant composition suitable for etching metals Cu/Mo of the present invention comprises hydrogen peroxide, amino acid, a pH stabilizer, fluorine-containing acid, an acidic pH adjuster, and an aqueous medium.

Without being bound by theory, it is believed that hydrogen peroxide used in the composition of the invention can oxidize Cu and Mo. According to one embodiment of the present invention, hydrogen peroxide is present in an amount ranging from 1 to 25 wt %, preferably from 3 to 20 wt %, on the basis of the total weight of the etchant composition.

Without being bound by theory, it is believed that amino acid used in the composition of the invention can etch Cu and Mo. According to one embodiment of the present invention, amino acid suitable for the composition of the invention includes, but is not limited to, glycine, alanine or a mixture thereof. The term “mixture” used here means a mixture of one or more of any amino acid mentioned above. Preferably, the amino acid used in the present invention is glycine or alanine The amount of amino acid used ranges from 0.1 to 15 wt %, preferably from 0.5 to 5 wt %, on the basis of the total weight of the etchant composition.

The pH stabilizer used in the present invention is to stabilize the pH value of the etchant composition. According to one embodiment of the present invention, the pH stabilizer suitable for the composition of the invention includes, but is not limited to, ammonium fluoride (NH₄F), ammonium bifluoride ((NH₄)HF₂), ethylenediamine tetraacetates (EDTA-salt), or a mixture thereof. The term “mixture” used here means a mixture of one or more of any pH stabilizers mentioned above. Preferably, the pH stabilizer used in the present invention is ammonium fluoride. The amount of pH stabilizer used ranges from 0.1 to 15 wt %, preferably from 0.8 to 3 wt %, on the basis of the total weight of the etchant composition.

Without being bound by theory, the fluorine-containing acid used in the present invention is to remove Mo residues from substrates. According to one embodiment of the present invention, the fluorine-containing acid suitable for the composition of the invention includes, but is not limited to, hydrofluoric acid (HF), fluorosilicic acid (H₂SiF₄), or a mixture thereof. The term “mixture” used here means a mixture of one or more of any fluorine-containing acid mentioned above. Preferably, the fluorine-containing acid used in the present invention is hydrofluoric acid. The amount of fluorine-containing acid used ranges from 0.01 to 2 wt %, preferably from 0.01 to 0.3 wt %, on the basis of the total weight of the etchant composition.

According to one embodiment of the present invention, the acidic pH adjuster suitable for the composition of the invention includes, but is not limited to, phosphoric acid (H₃PO₄), ammonium phosphate ((NH₄)H₂PO₄), acetic acid (CH₃COOH), oxalic acid (C₂H₂O₄), citric acid (C₆H₈O₇), or a mixture thereof. The term “mixture” used here means a mixture of one or more of any acidic pH adjuster mentioned above. Preferably, the acidic pH adjuster used in the present invention is phosphoric acid or ammonium phosphate. The amount of acidic pH adjuster used ranges from 0.01 to 3 wt %, preferably from 0.02 to 0.5 wt %, on the basis of the total weight of the etchant composition.

The acidic pH adjuster used in the present invention can adjust the pH of the etchant composition, so as to obtain a proper selection ratio of the Cu/Mo etching rate. According to one embodiment of the present invention, the pH of the etchant composition of the invention ranges from 4 to 6.5. Preferably the pH of the etchant composition of the invention is 5.

The aqueous medium used in this invention is well known to persons having ordinary skill in the art. For example, water, preferably deionized water, may be used in the preparation of the etchant composition of the invention.

Optionally, the etchant composition of the invention can further comprise other ingredients that are well known to persons having ordinary skill in the art and result in no adverse effect on the etchant composition of the invention.

The etchant composition of the invention has the advantages of achieving stable and uniform etching rates, and low under cut and appropriate under cut rim angle, when being used to form Cu/Mo electric circuit patterns. According to one embodiment of the present invention, the etchant composition of the invention is applicable to the etching processes of flat-panel displays, integrated circuits, flip chips, printed circuit boards, color filters, micro-electro machines, or other applications of Cu/Mo bi-layers.

Accordingly, the present invention further provides a process for etching metals Cu/Mo, comprising:
providing a substrate;
forming an Mo layer on the substrate;
forming a Cu layer on the Mo layer;
forming a patterned mask layer on the Cu layer; and
etching the Cu layer and Mo layer with an etchant composition having the ingredients and proportions defined above by means of the patterned mask layer.

According to one embodiment of the present invention, the Mo layer used in the process for etching metals Cu/Mo of the invention is formed from Mo or Mo alloys, and the Cu layer used in the process for etching metals Cu/Mo of the invention is formed from Cu or Cu alloys. Furthermore, the Mo layer and Cu layer are formed by physical vapor deposition (PVD), chemical vapor deposition (CVD), electroplating or electroless plating.

The substrates used in the process for etching metals Cu/Mo of the invention are well known to persons having ordinary skill in the art, e.g., glass substrates, silicone-wafer substrates, polyimide substrates, or epoxy-copper foil substrates.

According to one embodiment of the present invention, the patterned mask layer used in the process for etching metals Cu/Mo of the invention is formed by a photoresist.

According to one embodiment of the present invention, the Cu layer and Mo layer are etched at a temperature ranging from 15 to 40° C., preferably from 25 to 30° C.

The following examples are used to further illustrate the present invention, but not intended to limit the scope of the present invention. Any modifications or alterations that can easily be accomplished by persons having ordinary skill in the art fall within the scope of the disclosure of the specification and the appended claims.

### EXAMPLE

### (1) Preparation of Etchant Composition

Preparing an etchant composition including the following components:
8 wt % of hydrogen peroxide;
3 wt % of glycine;
2 wt % of ammonium fluoride;
0.02 wt % of hydrofluoric acid;
0.08 wt % of phosphoric acid; and
86.9 wt % of deionized water.

### (2) Etching Operations

An Mo layer and Cu layer are formed on a glass substrate in turn by physical vapor deposition, and then a protective photoresist is formed on the Cu layer, which defines etching patterns so as to form a testing substrate. The testing substrate is immersed in the etchant composition with the components mentioned above to conduct an etching process. The detailed conditions for etching operations are as follows:
Thickness of Cu/Mo: Cu 3000 Å/Mo 300 Å;
Etching temperature: 25° C.; and
Etching time: 90 seconds.

### (3) Results

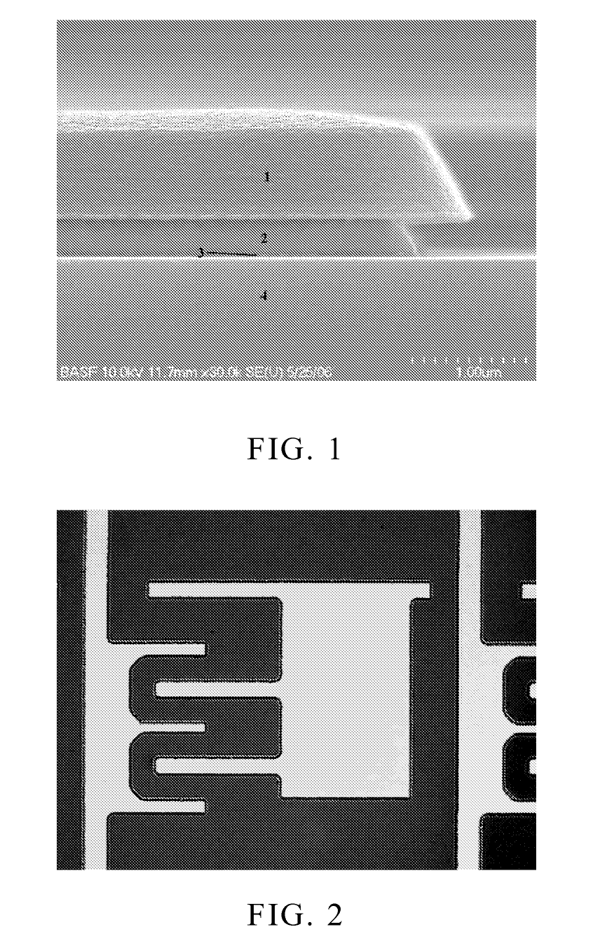

FIG. 1 is a side view of a laminate after it is etched with the etchant composition of the invention, wherein Symbol 1 refers to the photoresist layer, Symbol 2 refers to the Cu layer, Symbol 3 refers to the Mo layer, and symbol 4 refers to the glass substrate. FIG. 2 is an optical microscope photograph, enlarged 1000 times, of a laminate after it is etched with the etchant composition of the invention. As shown in FIG. 1, the CD loss of Cu/Mo wire after etching was small. The wire side was obliquely trapezoid. Furthermore, no under cut was observed from the Mo layer. The etching result was excellent.

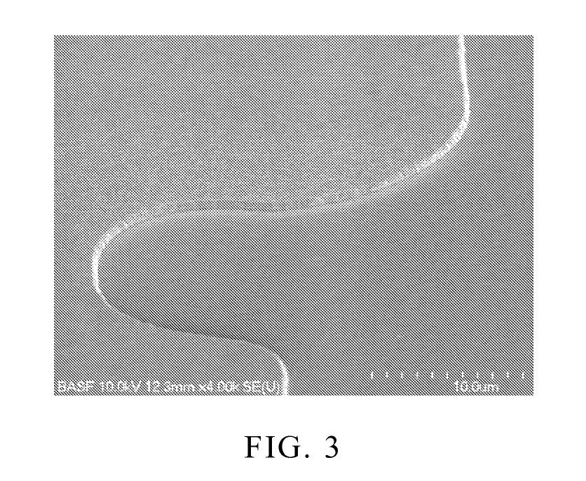

Subsequently, the photoresist layer is removed from the testing substrate after etching. The top view of scanning electron microscope (SEM) of the testing substrate is shown in FIG. 3. As shown in FIG. 3, the edge of Cu/Mo wire was smooth. The surface of the glass substrate was clean and had no metal residue.

It will be readily apparent that various modifications of the invention are possible and will readily suggest themselves to those skilled in the art and are contemplated.

1. An etchant composition suitable for etching Cu/Mo metals, comprising, on the basis of the total weight of the composition:
1 to 25 wt % of hydrogen peroxide;
0.1 to 15 wt % of amino acid;
0.1 to 15 wt % of a pH stabilizer;
0.01 to 2 wt % of fluorine-containing acid;
0.01 to 3 wt % of an acidic pH adjuster; and
an aqueous medium.

2. The etchant composition as claimed in claim 1, comprising, on the basis of the total weight of the composition:
3 to 20 wt % of hydrogen peroxide;
0.5 to 5 wt % of amino acid;
0.8 to 3 wt % of a pH stabilizer;
0.01 to 0.3 wt % of fluorine-containing acid;
0.02 to 0.5 wt % of an acidic pH adjuster; and
an aqueous medium.

3. The etchant composition as claimed in claim 1, wherein the aqueous medium is deionized water.

4. The etchant composition as claimed in claim 1, wherein the amino acid is selected from the group consisting of glycine, alanine, and a mixture thereof.

5. The etchant composition as claimed in claim 1, wherein the pH stabilizer is selected from the group consisting of ammonium fluoride (NH₄F), ammonium bifluoride ((NH₄)HF₂), ethylenediamine tetraacetates (EDTA-salt), and a mixture thereof.

6. The etchant composition as claimed in claim 1, wherein the fluorine-containing acid is selected from the group consisting of hydrofluoric acid (HF), fluorosilicic acid (H₂SiF₄), and a mixture thereof.

7. The etchant composition as claimed in claim 1, wherein the acidic pH adjuster is selected from the group consisting of phosphoric acid (H₃PO₄), ammonium phosphate ((NH₄)H₂PO₄), acetic acid (CH₃COOH), oxalic acid (C²H₂O₄), citric acid (C₆H₈O₇), and a mixture thereof.

8. The etchant composition as claimed in claim 1 having a pH ranging from 4 to 6.5.

9. The etchant composition as claimed in claim 1 for use in etching processes of flat-panel displays, integrated circuits, flip chips, printed circuit boards, color filters, micro-electro machines, or other applications of Cu/Mo bi-layers.

10. A process for etching Cu/Mo metals, comprising:
providing a substrate;
forming an Mo layer on the substrate;
forming a Cu layer on the Mo layer;
forming a patterned mask layer on the Cu layer; and
etching the Cu layer and Mo layer with the etchant composition of claim 1 by means of the patterned mask layer.

11. The process as claimed in claim 10, wherein the Mo layer is formed from Mo or Mo alloys, and the Cu layer is formed from Cu or Cu alloys.

12. The process as claimed in claim 10, wherein the Mo layer and Cu layer are formed by physical vapor deposition (PVD), chemical vapor deposition (CVD), electroplating or electroless plating.

13. The process as claimed in claim 10, wherein the patterned mask layer is formed by a photoresist.

14. The process as claimed in claim 10, wherein the Cu layer and Mo layer are etched at a temperature ranging from 15 to 40° C.
